(19) United States
(12) Patent Application Publication
(10) Pub. No.: US 2026/0371748 A1
(43) Pub. Date: Nov. 19, 2026

(54) SEMICONDUCTOR OPTICAL POSITION DETECTOR AND SEMICONDUCTOR OPTICAL POSITION DETECTOR ARRAY

(71) Applicant: HAMAMATSU PHOTONICS K.K., Hamamatsu-shi, Shizuoka (JP)

(72) Inventors: Keiki TAGUCHI, Hamamatsu-shi, Shizuoka (JP); Hajime ISHIHARA, Hamamatsu-shi, Shizuoka (JP)

(73) Assignee: HAMAMATSU PHOTONICS K.K., Hamamatsu-shi, Shizuoka (JP)

(21) Appl. No.: 19/475,907

(22) PCT Filed: Jan. 26, 2024
(86) PCT No.: PCT/JP2024/002497

§ 371 Date: Oct. 16, 2025

(30) Foreign Application Priority Data
Apr. 19, 2023 (JP) 2023-068703

(51) Int. Cl. H10F 39/10; H10F 77/124; H10F 77/14

(52) U.S. Cl. CPC H10F 39/107; H10F 77/1248; H10F 77/148

(57) ABSTRACT

A semiconductor optical position detector includes: a first semiconductor layer made of a first compound semiconductor and having a first conductivity type; a second semiconductor layer stacked on the first semiconductor layer and having bandgap energy larger than bandgap energy of the first compound semiconductor; a plurality of semiconductor regions formed in the second semiconductor layer so as to extend from a surface of the second semiconductor layer opposite to the first semiconductor layer toward the first semiconductor layer, and having a second conductivity type different from the first conductivity type; a surrounding region formed in the second semiconductor layer and surrounding at least a part of the plurality of semiconductor regions; and a first metal electrode and a second metal electrode provided on the second semiconductor layer.

### TECHNICAL FIELD

The present disclosure relates to a semiconductor optical position detector and a semiconductor optical position detector array.

### BACKGROUND ART

Patent Literature 1 describes a one-dimensional position detector. In this position detector, an InGaAs layer (i layer) and a p-type InP layer are formed on an n-type InP substrate. A cathode electrode is formed on a back surface of the n-type InP substrate, and a pair of electrodes is formed on both ends of a front surface of the p-type InP layer. In the position detector, a photocurrent generated according to incident light is divided in inverse proportion to a resistance value up to the pair of electrodes, and is detected in each of the pair of electrodes. In addition, the incident position is acquired based on a ratio of the currents in each of the pair of electrodes.

### CITATION LIST

### Patent Literature

Patent Literature 1: Japanese Unexamined Patent Publication No. 2002-033507

### SUMMARY OF INVENTION

### Problem to be Solved

Meanwhile, in the above technical field, there is a demand for manufacturing a position detector with a compound semiconductor material. However, in a compound semiconductor, since it is difficult to manufacture an element having a low carrier concentration, the resistance between the electrodes tends to be low. In this case, a current flows between the electrodes according to a minute potential difference, and noise may increase.

An object of the present disclosure is to provide a semiconductor optical position detector and a semiconductor optical position detector array capable of suppressing an increase in noise regardless of a material.

### Solution to Problem

A semiconductor optical position detector according to the present disclosure is [1] “a semiconductor optical position detector including: a first semiconductor layer made of a first compound semiconductor and having a first conductivity type; a second semiconductor layer stacked on the first semiconductor layer and having bandgap energy larger than bandgap energy of the first compound semiconductor; a plurality of semiconductor regions formed in the second semiconductor layer so as to extend from a surface of the second semiconductor layer opposite to the first semiconductor layer toward the first semiconductor layer, and having a second conductivity type different from the first conductivity type; a surrounding region formed in the second semiconductor layer and surrounding at least a part of the plurality of semiconductor regions; and a first metal electrode and a second metal electrode provided on the second semiconductor layer and arranged to be separated from each other along a second direction intersecting a first direction that is a stacking direction of the first semiconductor layer and the second semiconductor layer, wherein the plurality of semiconductor regions includes a first contact region being in contact with the first metal electrode, a second contact region being in contact with the second metal electrode and arranged to be separated from the first contact region along the second direction, and a plurality of island regions arranged along the second direction between the first contact region and the second contact region when viewed from the first direction, a carrier concentration of the second conductivity type in the surrounding region is lower than a peak of a carrier concentration of the second conductivity type in the island region, and each of the plurality of island regions is surrounded by the surrounding region when viewed from the first direction, and is not in contact with an electrode”.

In this detector, the plurality of semiconductor regions of the second conductivity type extending from the second semiconductor layer toward the first semiconductor layer are formed in the second semiconductor layer in which the first metal electrode and the second metal electrode separated from each other are formed. The plurality of semiconductor regions includes the plurality of island regions arranged in the arrangement direction (second direction) of the first metal electrode and the second metal electrode between the first contact region and the second contact region in contact with the first metal electrode and the second metal electrode, respectively. Each of the plurality of island regions is surrounded by the surrounding region in which the carrier concentration of the second conductivity type is lower than the peak of the carrier concentration of the second conductivity type in the island region, and is not in contact with the electrode. By forming the island region described above between the first metal electrode (first contact region) and the second metal electrode (second contact region), an energy barrier is formed between the island regions, and resistance between the first metal electrode and the second metal electrode can be increased. Therefore, according to this detector, it is possible to suppress an increase in noise due to the structure of the island region regardless of the material. Note that the carrier concentration of the second conductivity type in the surrounding region being lower than the peak of the carrier concentration of the second conductivity type in the island region includes a case where the surrounding region is of the second conductivity type, but the carrier concentration of the second conductivity type is lower than the peak, and a case where the carrier concentration of the second conductivity type is lower than the peak because the surrounding region is not of the second conductivity type (for example, the first conductivity type is dominant). Therefore, the conductivity type of the surrounding region is not limited.

A semiconductor optical position detector according to the present disclosure may be [2] “the semiconductor optical position detector according to the above [1], wherein the plurality of semiconductor regions is formed from the second semiconductor layer to the inside of the first semiconductor layer”. As described above, by forming the semiconductor region of the second conductivity type within the inside of the first semiconductor layer, sensitivity can be obtained without applying a voltage. Therefore, it is not necessary to prepare a voltage source, and measurement with a low dark current becomes possible.

A semiconductor optical position detector according to the present disclosure may be [3] “the semiconductor optical position detector according to the above [1] or [2], including: a third metal electrode and a fourth metal electrode provided on the second semiconductor layer and arranged to be separated from each other along a third direction intersecting the first direction and the second direction, wherein the plurality of semiconductor regions include a third contact region being in contact with the third metal electrode, and a fourth contact region being in contact with the fourth metal electrode and arranged to be separated from the third contact region along the third direction, and the plurality of island regions is arranged along the third direction between the third contact region and the fourth contact region”. In this case, two-dimensional position information including the second direction and the third direction can be acquired based on the output current from each of the first metal electrode to the fourth metal electrode.

A semiconductor optical position detector according to the present disclosure may be [4] “the semiconductor optical position detector according to any one of the above [1] to [3], wherein the surrounding region has the second conductivity type, and a lowest carrier concentration of the second conductivity type in the surrounding region is ¾ or less of the peak of the carrier concentration of the second conductivity type in the island region”. In this case, by further decreasing the carrier concentration, the energy barrier can be caused to be higher, and the resistance between the first metal electrode and the second metal electrode can be further increased.

A semiconductor optical position detector according to the present disclosure may be [5] “the semiconductor optical position detector according to any one of the above [1] to [4], wherein the second semiconductor layer has the first conductivity type, and a carrier concentration of the first conductivity type in the second semiconductor layer is 1×10¹⁶ or less”. In this case, it is possible to suppress an excessive increase in resistance between the first metal electrode and the second metal electrode, and to suppress deterioration of linearity.

A semiconductor optical position detector according to the present disclosure may be [6] “the semiconductor optical position detector according to any one of the above [1] to [5], including: a resistance adjustment region formed between the island regions adjacent to each other”. In this case, it is possible to prevent the resistance from being excessively increased and detect even high-intensity light with high linearity. Note that, as an example, the resistance adjustment region is a region in the regions outside the island region where the carrier concentration becomes relatively high by overlapping the regions where the carrier concentration becomes lower as the distance from the island region increases.

A semiconductor optical position detector according to the present disclosure may be [7] “the semiconductor optical position detector according to any one of the above [1] to [6], wherein each of the plurality of island regions has a circular shape when viewed from the first direction”. For example, in a case where the island region has a polygonal shape, there is a possibility that an electric field is concentrated at a corner portion. On the other hand, by making the island region circular in this way, concentration of the electric field in a part is avoided, and the electric field can be uniformly applied. By minimizing the closest sides between the circles, it is possible to prevent an excessive decrease in resistance.

A semiconductor optical position detector according to the present disclosure may be [8] “the semiconductor optical position detector according to any one of the above [1] to [7], wherein a carrier concentration of the second conductivity type in the semiconductor region is 1×10¹⁷ cm⁻³ or more”. In this case, the barrier at the time of PN junction can be increased by increasing the carrier concentration, and the dark current can be reduced.

A semiconductor optical position detector according to the present disclosure may be [9] “the semiconductor optical position detector according to any one of the above [1] to [8], wherein the first semiconductor layer is made of any of InGaAs, InAs, InAsSb, GaAs, GaN, and InGaN, or a mixed crystal thereof, and the second semiconductor layer is made of any of InP, InAsP, AlInP, AlInAsP, and GaN, or a mixed crystal thereof”. As described above, even in a compound semiconductor in which it is difficult to manufacture an optical position detector, it is possible to manufacture the optical position detector, and it is possible to manufacture an optical position detector having a high S/N ratio according to a wavelength corresponding to each material.

A semiconductor optical position detector array according to the present disclosure is [10] “a semiconductor optical position detector array including: a plurality of the semiconductor optical position detectors according to any one of the above [1] to [9], wherein the plurality of semiconductor optical position detectors are arranged along a direction intersecting the first direction and the second direction”. In this case, even in a case where a plurality of light is incident, signals corresponding to the respective light can be easily separated and detected.

### Advantageous Effects of Invention

According to the present disclosure, it is possible to provide a semiconductor optical position detector and a semiconductor optical position detector array capable of suppressing an increase in noise regardless of a material.

### BRIEF DESCRIPTION OF DRAWINGS

FIG. 1 is a schematic diagram illustrating a semiconductor optical position detector according to the present embodiment.

FIG. 2 is an enlarged schematic plan view illustrating an island region and a surrounding region illustrated in FIG. 1.

FIG. 3 is a graph illustrating a carrier concentration of a semiconductor region illustrated in FIG. 1.

FIG. 4 is a schematic plan view illustrating a semiconductor optical position detector according to a modification example.

FIG. 5 is a schematic plan view illustrating a semiconductor optical position detector according to a modification example.

FIG. 6 is a schematic plan view illustrating another modification example.

FIG. 7 is a schematic cross-sectional view illustrating still another modification example.

### DESCRIPTION OF EMBODIMENTS

Hereinafter, a semiconductor optical position detector and a semiconductor optical position detector array according to an embodiment will be described with reference to the drawings. Note that, in the description of each drawing, the same or corresponding elements are denoted by the same reference signs, and redundant description may be omitted. In addition, each drawing may illustrate an orthogonal coordinate system defined by an X axis, a Y axis, and a Z axis.

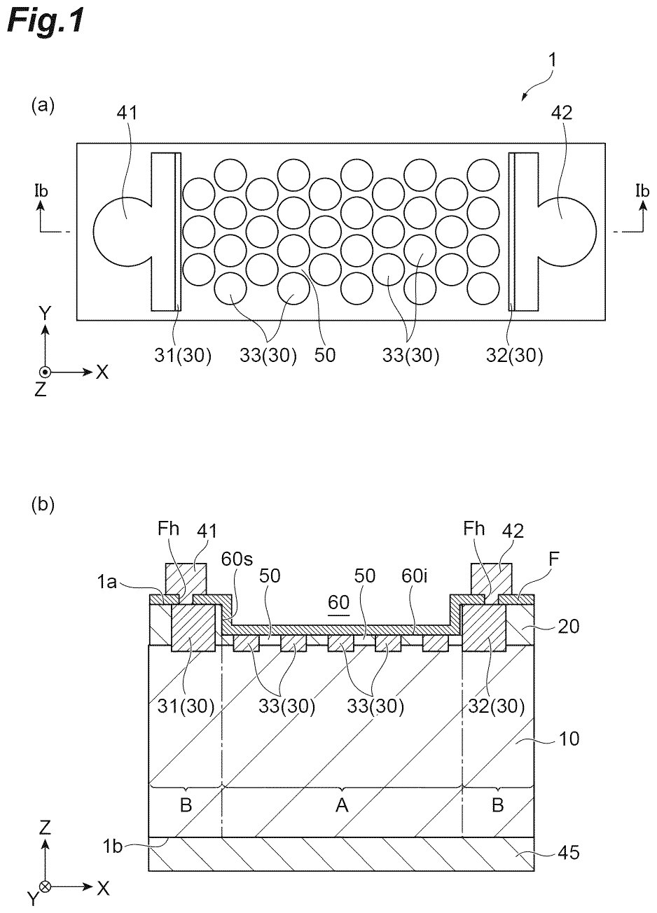

FIG. 1 is a schematic diagram illustrating a semiconductor optical position detector according to the present embodiment. (a) of FIG. 1 is a plan view, and (b) of FIG. 1 is a cross-sectional view taken along line Ib-Ib in FIG. 1. As illustrated in FIG. 1, a semiconductor optical position detector 1 includes a first semiconductor layer 10, a second semiconductor layer 20, a first metal electrode 41 and a second metal electrode 42, a common electrode 45, a plurality of semiconductor regions 30, and a protective film F. The semiconductor optical position detector 1 has a front surface 1a and a back surface 1b opposite to the front surface 1a. In the semiconductor optical position detector 1, for example, the front surface 1a is a light incident surface.

The semiconductor optical position detector 1 is, for example, a (one-dimensional) PSD (Position Sensitive Detector) that detects an incident position of light. In this case, in the semiconductor optical position detector 1, when spot light is incident from the front surface 1a side, a charge proportional to a light amount is generated at the incident position. This charge reaches the second semiconductor layer 20 as a photocurrent, is divided in inverse proportion to the distance to the first metal electrode 41 and the second metal electrode 42, and is extracted from the first metal electrode 41 and the second metal electrode 42. Based on values of output currents from the first metal electrode 41 and the second metal electrode 42, distances from the incident position to the first metal electrode 41 and the second metal electrode 42, and the like, the incident position of the spot light is obtained regardless of the light amount of the incident light or the like.

The first semiconductor layer 10 is made of a first compound semiconductor and has a first conductivity type (for example, an n-type). The first compound semiconductor is, for example, any of InGaAs, InAs, InAsSb, GaAs, GaN, and InGaN, or a mixed crystal thereof. The first semiconductor layer 10 includes the back surface 1b. The first semiconductor layer 10 includes a plurality of semiconductor layers stacked along a first direction (here, a Z-axis direction) intersecting the front surface 1a. The plurality of semiconductor layers include, for example, a substrate (not illustrated), a buffer layer (not illustrated), and a light absorbing layer (not illustrated) stacked in order from the back surface 1b side.

The substrate and the buffer layer are made of InP as an example. The buffer layer has a thickness of, for example, about 0.5 μm to 2.0 μm in the first direction. The light absorbing layer contains InGaAs (made of InGaAs) as an example. As an example, the light absorbing layer has a thickness of about 1.0 μm to 5 μm in the first direction.

The second semiconductor layer 20 is stacked on the first semiconductor layer 10. The second semiconductor layer 20 has band gap energy larger than band gap energy of the first compound semiconductor. The second semiconductor layer 20 has a first conductivity type (for example, an n-type). A carrier concentration of the first conductivity type of the second semiconductor layer 20 is, for example, 1×10¹⁶ cm⁻³ or less. As an example, the second compound semiconductor is any of InP, InAsP, AlInP, AlInAsP, and GaN, or a mixed crystal thereof.

The second semiconductor layer 20 includes the front surface 1a. The first direction (here, the Z-axis direction) is a direction intersecting the front surface 1a and the back surface 1b, and is also a stacking direction of the first semiconductor layer 10 and the second semiconductor layer 20. The second semiconductor layer 20 includes at least one cap layer (not illustrated). The cap layer is stacked on the light absorbing layer on the front surface 1a side of the light absorbing layer, and has an interface with the light absorbing layer.

Here, a recessed portion 60 is formed on the front surface 1a. As an example, the front surface 1a has a rectangular shape when viewed from the first direction, and the recessed portion 60 has a rectangular shape similar to that of the front surface 1a when viewed from the first direction. The recessed portion 60 includes a bottom surface 60i and a side surface 60s connecting the bottom surface 60i and the front surface 1a. The second semiconductor layer 20 (for example, a cap layer) is exposed on the bottom surface 60i of the recessed portion 60.

The first semiconductor layer 10 and the second semiconductor layer 20 include a first region A overlapping the bottom surface 60i of the recessed portion 60 when viewed from the first direction, and a second region B outside the first region A. In the semiconductor optical position detector 1, the first region A overlapping the bottom surface 60i of the recessed portion 60 when viewed from the first direction is configured to be thinner than the second region B outside the bottom surface 60i, and serves as a light receiving portion that receives incident light and generates a charge.

The protective film F is provided so as to cover the front surface 1a, the side surface 60s of the recessed portion 60, and the bottom surface 60i of the recessed portion 60. The protective film F may have a function as an antireflection film. In the protective film F, a through hole Fh is formed on the second region B, and the second semiconductor layer 20 (a first contact region 31 and a second contact region 32 to be described later) is exposed from the through hole Fh. The first metal electrode 41 and the second metal electrode 42 are arranged so as to be separated from each other along a second direction (here, an X-axis direction) intersecting the first direction, and are formed on the second semiconductor layer 20 with the protective film F interposed therebetween. The first metal electrode 41 and the second metal electrode 42 are in contact with the second semiconductor layer 20 through the through hole Fh. The common electrode 45 is formed on the back surface 1b and is in contact with the first semiconductor layer 10 (for example, a substrate).

The semiconductor region 30 is formed in the second semiconductor layer 20 so as to extend from a surface (front surface 1a) of the second semiconductor layer 20 opposite to the first semiconductor layer 10 toward the first semiconductor layer 10. In the present embodiment, the semiconductor region 30 is formed from the second semiconductor layer 20 to the inside of the first semiconductor layer 10 (reaches the inside of the first semiconductor layer 10). The semiconductor region 30 has a second conductivity type (for example, a p-type) different from the first conductivity type. Note that the semiconductor region 30 may not reach the inside of the first semiconductor layer 10.

The semiconductor region 30 becomes a region of the second conductivity type by doping the second semiconductor layer 20 and the first semiconductor layer 10 with impurities (for example, Zn). The semiconductor region 30 can be, for example, a diffusion region formed by doping impurities from the front surface 1a side by thermal diffusion. Alternatively, the semiconductor region 30 may be formed by doping impurities by an ion implantation method. A carrier concentration of the second conductivity type of the semiconductor region 30 is, for example, 1×10¹⁷ cm⁻³ or more.

The plurality of semiconductor regions 30 include a first contact region 31, a second contact region 32, and a plurality of island regions 33. The first contact region 31 is in contact with the first metal electrode 41 through the through hole Fh of the protective film F. The second contact region 32 is in contact with the second metal electrode 42 through the through hole Fh of the protective film F. The second contact region 32 is arranged to be separated from the first contact region 31 along the second direction.

The island regions 33 are arranged along the second direction between the first contact region 31 and the second contact region 32. In the present embodiment, the island regions 33 are uniformly arranged in a plane including a third direction (here, a Y-axis direction) intersecting the first direction and the second direction, and the second direction. The island region 33 has a circular shape when viewed from the first direction. The island regions 33 are separated from each other. In the present embodiment, a contact portion between the first metal electrode 41 and the first contact region 31 and a contact portion between the second metal electrode 42 and the second contact region 32 linearly extend over an entire range in which the island region 33 is distributed in the third direction (over the entire first metal electrode 41 and second metal electrode 42).

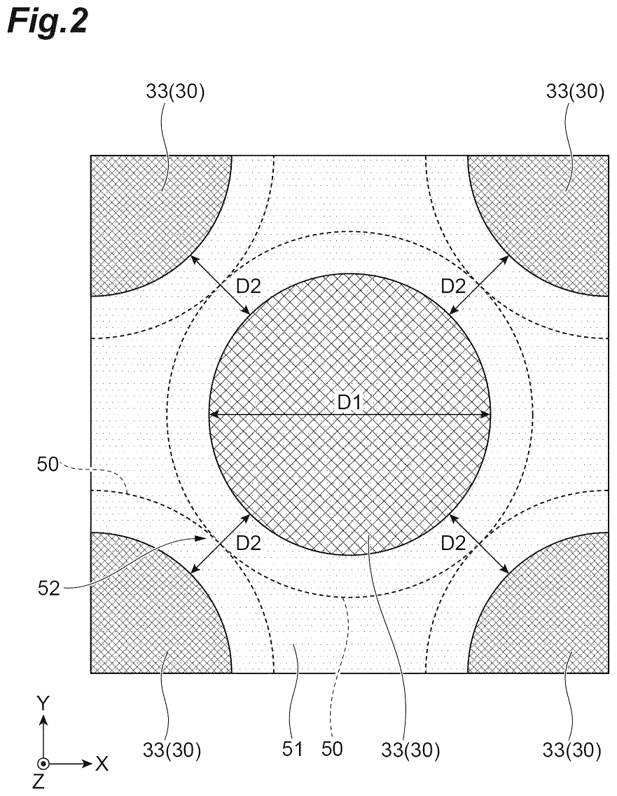

As illustrated in FIGS. 1 and 2, the semiconductor optical position detector 1 includes a surrounding region 50 that is formed in the second semiconductor layer 20 and surrounds at least a part of the plurality of semiconductor regions 30 when viewed from the first direction. The surrounding region 50 surrounds at least the island regions 33 when viewed from the first direction.

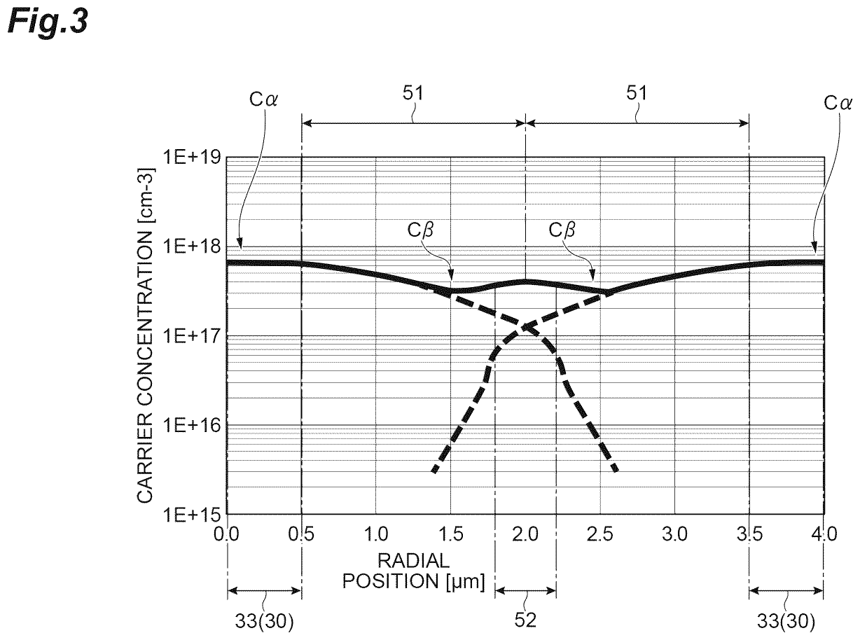

The surrounding region 50 is formed in a ring shape (here, circular ring shape) around the island region 33. A non-diffusion region 51 is formed outside the surrounding region 50. In the present embodiment, the surrounding region 50 is a region where impurities diffuse when the island region 33 is formed. Therefore, as illustrated in FIG. 3, the surrounding region 50 is of the second conductivity type and has a carrier concentration lower than the carrier concentration of the second conductivity type of the island region 33. More specifically, the carrier concentration of the surrounding region 50 decreases as the distance from the center of the island region 33 increases in a radial direction.

However, the adjacent surrounding regions 50 have overlapping regions 52 that overlap at the outer edge portions thereof, and the carrier concentration is added and increased in the overlapping regions 52. Therefore, the presence of the overlapping region 52 between the island regions 33 suppresses electrical resistance from becoming too high. In other words, the overlapping region 52 is a resistance adjustment region. Further, in other words, the semiconductor optical position detector 1 includes the resistance adjustment region formed between the adjacent island regions 33. However, the resistance adjustment region is not essential and may not be provided.

Note that a lowest carrier concentration Cβ of the second conductivity type in the surrounding region 50 is ¾ or less of a peak value Cα of the carrier concentration of the second conductivity type in the island region 33. Alternatively, the carrier concentration Cβ is desirably ⅔ or less of the peak value Cα, and more desirably ½ or less. In the present embodiment, an interval D2 between the island regions 33 closest to each other is, for example, about 3 μm, and is smaller than a diameter D1 (for example, about 10 μm) of the island region 33. In addition, the non-diffusion region 51 may be of the first conductivity type.

As described above, each of the plurality of island regions 33 is surrounded by the surrounding region 50 when viewed from the first direction, and is not in contact with an electrode. A state in which the island region 33 is not in contact with the electrode means that the island region is not in direct contact with the first metal electrode 41, the second metal electrode 42, or the like, and the island region is not in contact with a member, a layer, or the like having resistance lower than that of the second semiconductor layer 20, such as a wire or another electrode electrically connected to the first metal electrode 41 or the second metal electrode 42.

As described above, in the semiconductor optical position detector 1, the plurality of semiconductor regions 30 of the second conductivity type extending from the second semiconductor layer 20 toward the first semiconductor layer 10 are formed in the second semiconductor layer 20 in which the first metal electrode 41 and the second metal electrode 42 separated from each other are formed. The plurality of semiconductor regions 30 include the plurality of island regions 33 arranged in the second direction between the first contact region 31 and the second contact region 32 in contact with the first metal electrode 41 and the second metal electrode 42, respectively.

Each of the plurality of island regions 33 is surrounded by the surrounding region 50 in which the carrier concentration of the second conductivity type is lower than the peak of the carrier concentration of the second conductivity type in the island region 33, and is not in contact with the electrode. By forming the island region 33 described above between the first metal electrode 41 (first contact region 31) and the second metal electrode 42 (second contact region 32), an energy barrier is formed between the island regions 33, and electrical resistance between the first metal electrode 41 and the second metal electrode 42 can be increased. Therefore, according to the semiconductor optical position detector 1, it is possible to suppress an increase in noise due to the structure of the island region 33 regardless of the material.

In the semiconductor optical position detector 1, the plurality of semiconductor regions 30 are formed from the second semiconductor layer 20 to the inside of the first semiconductor layer 10. As described above, by forming the semiconductor region 30 of the second conductivity type over the inside of the first semiconductor layer 10, sensitivity can be obtained without applying a voltage. Therefore, it is not necessary to prepare a voltage source, and measurement with a low dark current becomes possible.

In the semiconductor optical position detector 1, the surrounding region 50 has the second conductivity type, and the lowest carrier concentration Cβ of the second conductivity type of the surrounding region 50 is ¾ or less of the peak value Cα of the carrier concentration of the second conductivity type of the island region 33. Therefore, the energy barrier can be caused to be higher by further decreasing the carrier concentration, and the resistance between the first metal electrode 41 and the second metal electrode 42 can be further increased.

In the semiconductor optical position detector 1, the second semiconductor layer 20 has the first conductivity type, and the carrier concentration of the first conductivity type of the second semiconductor layer 20 is 1×10¹⁶ or less. Therefore, it is possible to suppress an excessive increase in resistance between the first metal electrode 41 and the second metal electrode 42, and to suppress deterioration of linearity.

Further, the semiconductor optical position detector 1 includes the resistance adjustment region (overlapping region 52) formed between the island regions 33 adjacent to each other. Therefore, it is possible to prevent the resistance from being excessively increased and detect even high-intensity light with high linearity. As an example, the resistance adjustment region is a region where the carrier concentration becomes relatively high in the regions (surrounding regions 50) outside the island regions by overlapping the regions (surrounding regions 50) where the carrier concentration becomes lower as the distance from the island region increases.

In the semiconductor optical position detector 1, each of the plurality of island regions 33 has a circular shape when viewed from the first direction. By forming the island region 33 in a circular shape as described above, in a case where the island region 33 is formed in a polygonal shape, concentration of an electric field at a corner portion is avoided, and the electric field can be uniformly applied. By minimizing the closest sides between the circles, it is possible to prevent an excessive decrease in resistance.

In the semiconductor optical position detector 1, the carrier concentration of the second conductivity type of the semiconductor region 30 is 1×10¹⁷/cm³ or more. Therefore, by increasing the carrier concentration, the barrier at the time of PN junction can be increased, and the dark current can be reduced.

Further, in the semiconductor optical position detector 1, the first semiconductor layer 10 is made of any of InGaAs, InAs, InAsSb, GaAs, GaN, and InGaN, or a mixed crystal thereof, and the second semiconductor layer 20 is made of any of InP, InAsP, AlInP, AlInAsP, and GaN, or a mixed crystal thereof. As described above, even in a compound semiconductor in which it is difficult to manufacture an optical position detector, it is possible to manufacture the optical position detector, and it is possible to manufacture an optical position detector having a high S/N ratio according to a wavelength corresponding to each material.

The above embodiment describes one aspect of the semiconductor optical position detector according to the present invention. Therefore, the present invention is not limited to the semiconductor optical position detector 1 according to the above embodiment, and can be arbitrarily modified. Subsequently, modification examples will be described.

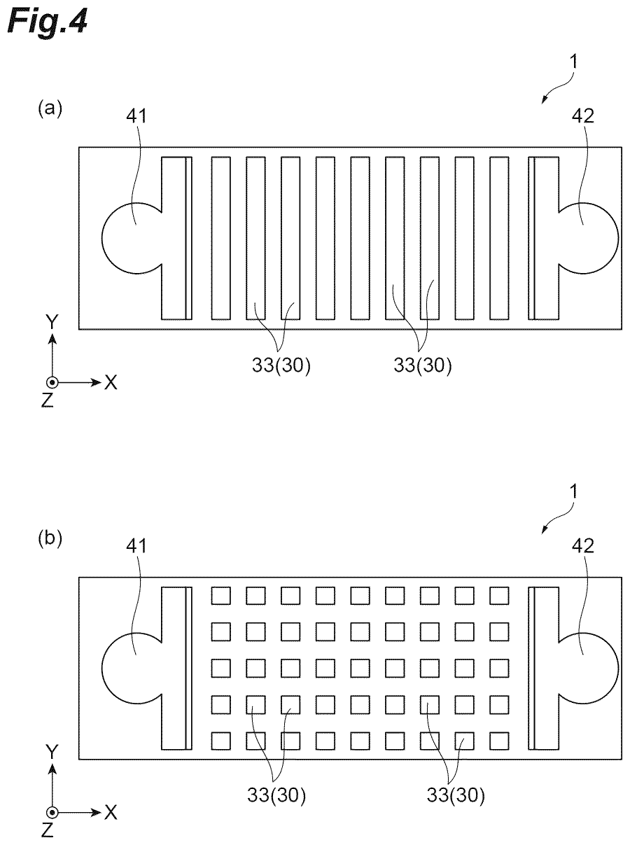

FIG. 4 is a schematic plan view illustrating a semiconductor optical position detector according to a modification example; In the above embodiment, the aspect in which the circular island regions 33 are arranged two-dimensionally when viewed from the first direction has been described, but as illustrated in (a) of FIG. 4, the island regions 33 may be formed in a long rectangular shape when viewed from the first direction. In the example of (a) of FIG. 4, the plurality of island regions 33 extending over the entire region in the third direction sandwiched between the first metal electrode 41 and the second metal electrode 42 are one-dimensionally arranged along the second direction while being separated from each other. In this case, the shape of the surrounding region 50 surrounding the island region 33 may be a long rectangular ring shape along the outer shape of the island region 33.

Further, as illustrated in (b) of FIG. 4, the island region 33 may be formed in a square shape when viewed from the first direction. In the example of (b) of FIG. 4, a plurality of island regions 33 having a square shape when viewed from the first direction are uniformly arranged two-dimensionally along the second direction and the third direction while being separated from each other. In this case, the shape of the surrounding region 50 surrounding the island region 33 may be a square ring shape along the outer shape of the island region 33.

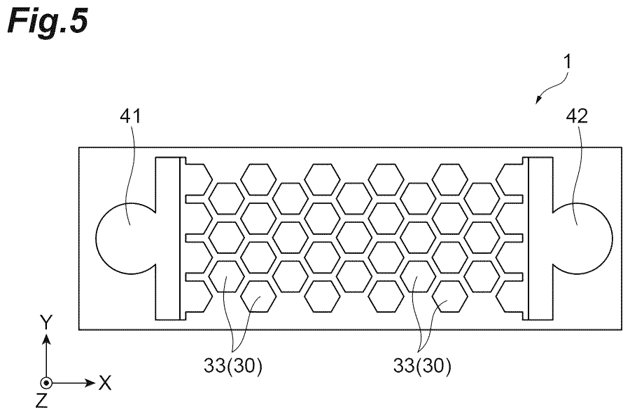

Further, as illustrated in FIG. 5, the island region 33 may be formed in a hexagonal shape when viewed from the first direction. In the example of FIG. 5, a plurality of island regions 33 having a hexagonal shape when viewed from the first direction are uniformly arranged two-dimensionally along the second direction and the third direction while being separated from each other. In this case, the shape of the surrounding region 50 surrounding the island region 33 may be a hexagonal ring shape along to the outer shape of the island region 33. As described above, the island region 33 is not limited to a circular shape, and may have any polygonal shape. Furthermore, the island region 33 is not limited to a circular shape or a polygonal shape, and may have any shape (for example, an elliptical shape).

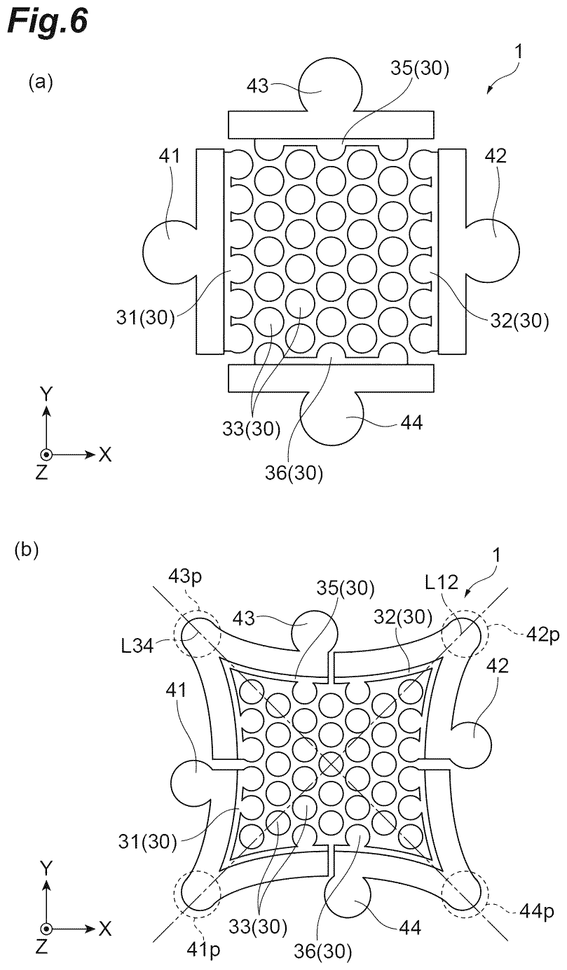

FIG. 6 is a schematic plan view illustrating another modification example. As illustrated in (a) of FIG. 6, the semiconductor optical position detector 1 may further include a third metal electrode 43 and a fourth metal electrode 44. In the example of (a) of FIG. 6, the third metal electrode 43 and the fourth metal electrode 44 are arranged to be separated from each other along the third direction. The semiconductor region 30 further includes a third contact region 35 that is in contact with the third metal electrode 43 and a fourth contact region 36 that is in contact with the fourth metal electrode 44 and is arranged to be separated from the third contact region 35 along the third direction.

The island region 33 is arranged along the third direction between the third contact region 35 and the fourth contact region 36. Here, when viewed from the first direction, a plurality of circular island regions 33 are two-dimensionally arranged over the entire rectangular region surrounded by the first metal electrode 41 (first contact region 31), the second metal electrode 42 (second contact region 32), the third metal electrode 43 (third contact region 35), and the fourth metal electrode 44 (fourth contact region 36).

In the example of (a) of FIG. 6, a contact portion between the first metal electrode 41 and the first contact region 31 and a contact portion between the second metal electrode 42 and the second contact region 32 linearly extend over the entire range in which the island region 33 is distributed in the third direction (over the entire first metal electrode 41 and second metal electrode 42). In addition, a contact portion between the third metal electrode 43 and the third contact region 35 and a contact portion between the fourth metal electrode 44 and the fourth contact region 36 linearly extend over the entire range in which the island region 33 is distributed in the second direction (over the entire third metal electrode 43 and fourth metal electrode 44).

According to the modification example of (a) of FIG. 6 described above, two-dimensional position information including the second direction and the third direction can be acquired based on the output current from each of the first metal electrode 41, the second metal electrode 42, the third metal electrode 43, and the fourth metal electrode 44.

In the example of (b) of FIG. 6, each of the first metal electrode 41, the second metal electrode 42, the third metal electrode 43, and the fourth metal electrode 44 is formed in an L shape by a portion extending along the second direction and a portion extending along the third direction. The first metal electrode 41, the second metal electrode 42, the third metal electrode 43, and the fourth metal electrode 44 are arranged such that a corner portion 41p of the first metal electrode 41, a corner portion 42p of the second metal electrode 42, a corner portion 43p of the third metal electrode 43, and a corner portion 44p of the fourth metal electrode 44 are four corners of a quadrangle. In addition, the first metal electrode 41 and the second metal electrode 42 are arranged so as to face each other along one diagonal line L12, and the third metal electrode 43 and the fourth metal electrode 44 are arranged so as to face each other along another diagonal line L34.

The first metal electrode 41 and the first contact region 31 are in contact with each other only at the corner portion 41p, the second metal electrode 42 and the second contact region 32 are in contact with each other only at the corner portion 42p, the third metal electrode 43 and the third contact region 35 are in contact with each other only at the corner portion 43p, and the fourth metal electrode 44 and the fourth contact region 36 are in contact with each other only at the corner portion 44p. Therefore, in the example of (b) of FIG. 6, a direction of position detection is a direction along the diagonal line L12 and a direction along the diagonal line L34.

In other words, in the example of (b) of FIG. 6, by replacing the direction along the diagonal line L12 with a new second direction and the direction along the diagonal line L34 with a new third direction, the first metal electrode 41 and the second metal electrode 42 are arranged while being separated from each other along the second direction, and the third metal electrode 43 and the fourth metal electrode 44 are arranged while being separated from each other along the third direction. In addition, the island regions 33 are arranged along the second direction and the third direction.

Portions other than the corner portions 41p, 42p, 43p, and 44p of the first metal electrode 41, the second metal electrode 42, the third metal electrode 43, and the fourth metal electrode 44 (portions not in contact with the semiconductor region 30) are provided for light shielding for limiting the light receiving portion.

According to the modification example of (b) of FIG. 6 described above, two-dimensional position information including the second direction and the third direction can be acquired based on the output current from each of the first metal electrode 41, the second metal electrode 42, the third metal electrode 43, and the fourth metal electrode 44.

Furthermore, although not illustrated, the semiconductor optical position detector 1 may be configured as a double-sided split PSD. In this case, the first metal electrode 41 and the second metal electrode 42 are formed on the front surface 1a side, and the third metal electrode 43 and the fourth metal electrode 44 are formed on the back surface 1b side.

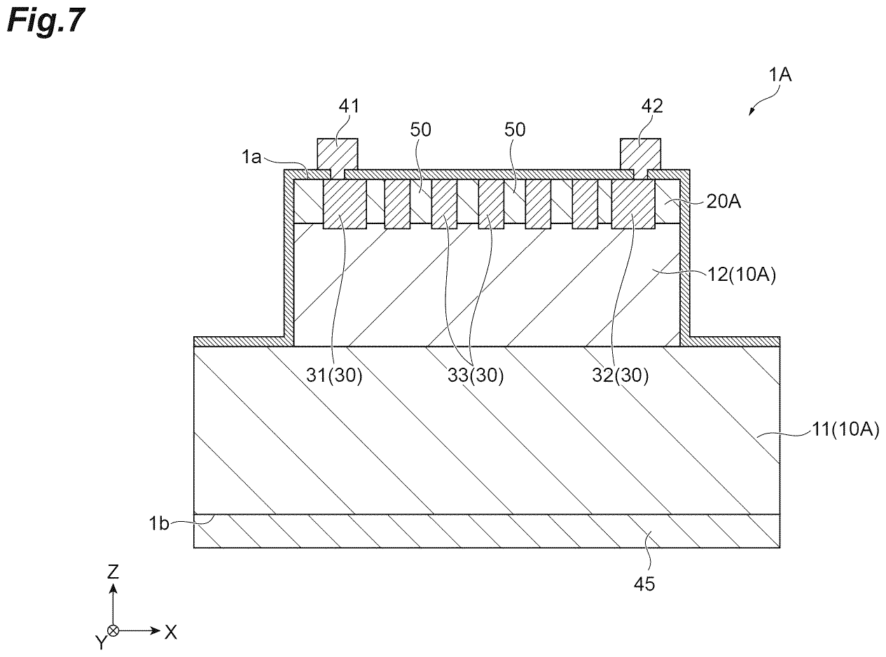

FIG. 7 is a schematic cross-sectional view illustrating still another modification example. A semiconductor optical position detector 1A illustrated in FIG. 7 is different from the semiconductor optical position detector 1 according to the embodiment in including a first semiconductor layer 10A instead of the first semiconductor layer 10 and a second semiconductor layer 20A instead of the second semiconductor layer 20. The first semiconductor layer 10A includes a first layer 11 having a first conductivity type (for example, an n-type) and a second layer 12 having the first conductivity type and stacked on a part of the first layer 11. The first layer 11 is made of, for example, N—InP, and the second layer 12 is made of, for example, N—InGaAs. The second semiconductor layer 20A has a second conductivity type (for example, a p-type), and is stacked on the second layer 12 of the first semiconductor layer 10A. The second semiconductor layer 20A is made of, for example, P—InP.

The second semiconductor layer 20A includes a front surface 1a. The semiconductor region 30 is formed in the second semiconductor layer 20A so as to extend from a surface (front surface 1a) of the second semiconductor layer 20A opposite to the first semiconductor layer 10A toward the first semiconductor layer 10A. Here, the semiconductor region 30 is formed from the second semiconductor layer 20A to the inside of the first semiconductor layer 10A. As described above, the semiconductor region 30 having the second conductivity type may be formed inside the second semiconductor layer 20A having the second conductivity type. At this time, a carrier concentration of the second conductivity type of the second semiconductor layer 20A can be, for example, about 1×10¹⁴ cm⁻³ to 1×10¹⁶ cm⁻³.

Although the semiconductor optical position detectors 1 and 1A have been described above, a plurality of the semiconductor optical position detectors 1 and 1A may be provided, and the plurality of semiconductor optical position detectors 1 and 1A may be arranged along a direction intersecting the first direction and the second direction to form a semiconductor optical position detector array.

### INDUSTRIAL APPLICABILITY

A semiconductor optical position detector and a semiconductor optical position detector array capable of suppressing an increase in noise regardless of a material are provided.

### REFERENCE SIGNS LIST

1, 1A Semiconductor optical position detector
10,10A First semiconductor layer
20, 20A Second semiconductor layer
30 Semiconductor region
31 First contact region
32 Second contact region
33 Island region
35 Third contact region
36 Fourth contact region
41 First metal electrode
42 Second metal electrode
43 Third metal electrode
44 Fourth metal electrode
50 Surrounding region
52 Overlapping region (resistance adjustment region)

1. A semiconductor optical position detector comprising:
a first semiconductor layer made of a first compound semiconductor and having a first conductivity type;
a second semiconductor layer stacked on the first semiconductor layer and having bandgap energy larger than bandgap energy of the first compound semiconductor;
a plurality of semiconductor regions formed in the second semiconductor layer so as to extend from a surface of the second semiconductor layer opposite to the first semiconductor layer toward the first semiconductor layer, the plurality of semiconductor regions having a second conductivity type different from the first conductivity type;
a surrounding region formed in the second semiconductor layer and configured to surround at least a part of the plurality of semiconductor regions; and
a first metal electrode and a second metal electrode provided on the second semiconductor layer and arranged to be separated from each other along a second direction intersecting a first direction that is a stacking direction of the first semiconductor layer and the second semiconductor layer, wherein
the plurality of semiconductor regions includes
a first contact region being in contact with the first metal electrode,
a second contact region being in contact with the second metal electrode and arranged to be separated from the first contact region along the second direction, and
a plurality of island regions arranged along the second direction between the first contact region and the second contact region when viewed from the first direction,
a carrier concentration of the second conductivity type in the surrounding region is lower than a peak of a carrier concentration of the second conductivity type in the island region, and
each of the plurality of island regions is surrounded by the surrounding region when viewed from the first direction, and is not in contact with an electrode.

2. The semiconductor optical position detector according to claim 1, wherein the plurality of semiconductor regions is formed from the second semiconductor layer to the inside of the first semiconductor layer.

3. The semiconductor optical position detector according to claim 1, comprising:
a third metal electrode and a fourth metal electrode provided on the second semiconductor layer and arranged to be separated from each other along a third direction intersecting the first direction and the second direction, wherein
the plurality of semiconductor regions includes
a third contact region being in contact with the third metal electrode, and
a fourth contact region being in contact with the fourth metal electrode and arranged to be separated from the third contact region along the third direction, and
the plurality of island regions is arranged along the third direction between the third contact region and the fourth contact region.

4. The semiconductor optical position detector according to claim 1, wherein
the surrounding region has the second conductivity type, and
a lowest carrier concentration of the second conductivity type in the surrounding region is ¾ or less of the peak of the carrier concentration of the second conductivity type in the island region.

5. The semiconductor optical position detector according to claim 1, wherein
the second semiconductor layer has the first conductivity type, and
a carrier concentration of the first conductivity type in the second semiconductor layer is 1×10¹⁶ cm⁻³ or less.

6. The semiconductor optical position detector according to claim 1, comprising:
a resistance adjustment region formed between the island regions adjacent to each other.

7. The semiconductor optical position detector according to claim 1, wherein
each of the plurality of island regions has a circular shape when viewed from the first direction.

8. The semiconductor optical position detector according to claim 1, wherein
a carrier concentration of the second conductivity type in the semiconductor region is 1×10¹⁷ cm⁻³ or more.

9. The semiconductor optical position detector according to any one of claim 1, wherein
the first semiconductor layer is made of any of InGaAs, InAs, InAsSb, GaAs, GaN, and InGaN, or a mixed crystal thereof, and
the second semiconductor layer is made of any of InP, InAsP, AlInP, AlInAsP, and GaN, or a mixed crystal thereof.

10. A semiconductor optical position detector array comprising:
a plurality of the semiconductor optical position detectors according to claim 1, wherein
the plurality of semiconductor optical position detectors is arranged along a direction intersecting the first direction and the second direction.
